(19) United States
(12) Patent Application Publication
(10) Pub. No.: US 2012/0146667 A1
(43) Pub. Date: Jun. 14, 2012

(54) RADIO FREQUENCY DETECTOR COILS

(76) Inventors: Richard Rodney Anthony Syms, London (GB); Simon Taylor-Robinson, London (GB); Munir M. Ahmad, Surrey (GB); Ian Robert Young, Wiltshire (GB)

(21) Appl. No.: 13/377,669

(22) PCT Filed: Jun. 11, 2010
(86) PCT No.: PCT/GB2010/050982

§ 371 Date: Feb. 27, 2012

(30) Foreign Application Priority Data
Jun. 11, 2009 (GB) 0910039.7
Mar. 22, 2010 (GB) 1004721.5

(51) Int. Cl. G01R 27/04

(52) U.S. Cl. 324/629

(57) ABSTRACT

A resonant radiofrequency (RF) detector assembly comprising a substrate, a coil formed on a front surface of the substrate, and two capacitors, each capacitor having a front plate which is formed on the front surface of the substrate and a rear plate formed on a rear surface of the substrate, the two front plates each being electrically connected to a different end of the coil, and the two rear plates being electrically connected to each other.

### FIELD OF THE INVENTION

The present invention relates to radio frequency (RF) detector coils. It has application, for example, in magnetic resonance (MR) imaging and monitoring systems.

### BACKGROUND TO THE INVENTION

Small resonant RF detectors have many applications for in-vivo internal magnetic resonance imaging (MRI). Although small coils generally have low Q-factors, this disadvantage is mitigated by the overall increase in signal-to-noise ratio obtained from close coupling to the source. Suitable coil arrangements include single- or multi-turn loops, parallel conductor transmission lines, opposed solenoids and meanders. More compact alternatives for intravascular imaging include the so-called “loopless catheter antenna”, which measures electric rather than magnetic fields. A similar range of coils has been used for the alternative application of catheter tracking.

In each case, the need for matching and tuning has limited widespread clinical application. This problem can be illustrated as follows. Generally, the coil (which has inductance L and resistance R) must be matched to a load R_{L} at the angular frequency ω₀ at which the coil is to resonate. FIG. 1a shows one approach, which uses a first capacitor C_{M} for matching and a second capacitor C_{T} for tuning. Standard analysis shows that the parallel arrangement of C_{M} and R_{L} may be replaced with a series arrangement of C_{M} and an equivalent load R_{L}′, which depends on R_{L}, C_{M} and ω₀, as shown in FIG. 1b. Matching requires that R_{L}′=R, which in turn requires that C_{M} be chosen appropriately. The series sum of C_{M} and C_{T} is clearly equivalent to a single capacitor C as shown in FIG. 1c. Once C_{M} is fixed, C_{T} should therefore be chosen so that C is the total capacitance needed for resonance.

Despite advances in modelling methods that allow for 3D coils, skin effects and material losses, it is unfortunately difficult to predict either the resistance R or the inductance L accurately. The coil resistance is inherently frequency-dependent, joints provide further resistive losses, self-capacitance strongly affects resonant frequency, and hand winding introduces variability. Consequently, both C_{M} and C_{T} must generally be determined experimentally, using values that are successively updated to improve the degree of matching and the resonant frequency. The restricted set of readily available capacitance values generally forces the use of multiple components for both C_{M} and C_{T}. As a result, the final assembly is often bulky, and may have been soldered and re-soldered many times. For large coils, the end product may be acceptable, but the general approach cannot achieve the low cost, small form factor and reproducibility needed for mass deployment of catheter-based probes, especially disposable ones. One solution is to locate the matching and tuning components remotely, using a λ/2 length of cable. This approach allows a suitable form factor. Matching and tuning can also be carried out using automated varactor-based systems. However, both solutions are generally too complex for low-cost, mass-produced coils.

Micro-fabrication can improve the situation, since it allows repeatable values of R and L to be obtained. Electroplated spiral coils have been formed on rigid substrates such as GaAs, Si and glass. Micro-fabricated Helmholtz coils and gradient coils have been constructed, solenoids have been fabricated on capillaries, planar coils have been integrated with micro-fluidics, and pre-amplifiers incorporated. More recently, attention has turned to flexible plastics such as polyimide and polyether-ether-ketone [Coutrot A.-L., Dufour-Gergam E., Quemper J.-M., Martincic E., Gilles J.-P., Grandchamp J. P., Matlosz M., Sanchez A., Darasse L., Ginefri J.-C. “Copper micromolding process for NMR microinductors realisation” Sensors and Actuators A99, 49-54 (2002)] and polytetrafluoroethylene [Eroglu S., Gimi B., Roman B., Friedman G., Magin R. L. “NMR spiral surface microcoils: design, fabrication and imaging” Conc. Mag. Res. B 17, 1-10 (2003)], which are much more suitable for in-vivo use, and flexible 3D coils have been constructed [Woytasik M., Grandchamp J.-P., Dufour-Gergam E., Martincic E., Gilles J.-P., Megherbi S., Lavally V., Mathet V. “Fabrication of planar and three-dimensional microcoils on flexible substrates” Microsyst. Tech. 12, 973-978 (2006)]. However, matching and tuning have largely been ignored. Some attempts have been made to integrate capacitors, using coplanar conductors [Ellersiek D., Harms S., Casanova F., Blümich B., Mokwa W., Schnakenberg U. “Flexible RF microcoils with integrated capacitor for NMR applications” Proc. MME'05, Göteborg, Sweden, September 4-6, pp 256-259 (2005)], double-layer windings [Woytaskik M., Ginefri J.-C., Raynaud J.-S., Poirier-Wuinot M., Dufour-Gergam E., Grandchamp J.-P., Girard O., Robert P., Gilles J.-P., Martincic E., Darasse L. “Characterisation of flexible RF microcoils dedicated to local MRI” Microsyst. Tech. 13, 1575-1580 (2007)] or optically-variable MOS structures [Uelzen Th., Fandrey S., Müller J. “Mechanical and electrical properties of electroplated copper for MR-imaging coils” Microsyst. Tech. 12, 343-351 (2006)]. Previously [Ahmad M. M., Syms R. R. A., Young I. R., Mathew B., Casperz W., Taylor-Robinson S. D., Wadsworth C. A., Gedroyc W. M. W. “Catheter-based flexible microcoil RF detectors for internal magnetic resonance imaging” J. Micromech. Microeng., submitted], it has been demonstrated that high-resolution MRI using catheter mounted microfabricated coils with discrete capacitors, based on the multi-turn rectangular spiral inductor can be produced However, no convincing solution has yet been found to the problem of optimising component values without expensive iteration of planar processing.

### SUMMARY OF THE INVENTION

The present invention provides a resonant radiofrequency (RF) detector comprising a substrate, an inductor coil formed on a front surface of the substrate, and two capacitors, each capacitor having a front plate formed on the front surface of the substrate and a rear plate formed on the rear surface of the substrate. The two front surface capacitor plates are each connected electrically to a different end of the coil, and the two rear capacitor plates are connected electrically to each other, so that the whole circuit represents a resonant electrical loop containing one inductor and two capacitors.

The resonant circuit may then provide the function of detecting RF signals. One capacitor C_{M} may then provide the function of matching the electrical impedance seen across its plates at a target resonant frequency to a target value while the other capacitor C_{T} may provide the function of tuning the resonant frequency of the circuit to a target value.

The coil may comprise one or more full turns, or it may comprise one or more half turns, or part turns, or it may be of any other suitable shape for detecting a RF signal. The front plate of one of the capacitors may be formed within the coil. The front plate of one of the capacitors may be formed outside the coil. The two rear capacitor plates may be formed from a common layer of conductive material. Connections between the two capacitors may also be formed in the same common layer of material. A similar approach may be use to add additional coils and capacitors in series.

The coil may have two sections and each of the front plates may be connected to an end of a respective one of the sections. In some cases the sections each have a respective winding sense, the winding senses being opposite to each other. For example the winding may be arranged in a figure-of-eight configuration. The sections may each have the same number of turns, or may be otherwise arranged so as to have the same, or substantially the same, inductance. Each of the coil sections may form a respective loop and each of the front plates may be inside a respective one of the loops.

The substrate may be thin, to allow capacitors of a given size to be formed using a small surface area. Using a thin substrate, the inductor and capacitors may be flexible. The whole assembly may therefore be flexible so that it can be wrapped around a catheter.

The present invention further provides a method of producing an RF detector assembly comprising:
providing a substrate;
forming a coil on a front surface of the substrate;
forming two front capacitor plates on the front surface of the substrate; forming two rear capacitor plates on a rear surface of the substrate each at least partially aligned with one of the front capacitor plates to form a capacitor
providing electrical connections between each of the front capacitor plates and a different end of the coil,
and providing electrical connections between the two rear capacitor plates.

The coil and the front capacitor plates may be formed simultaneously, or they may be formed separately in separate steps. The coil and the front capacitor plates may be formed as a common layer of conductive material. The two rear capacitor plates may be formed simultaneously, and may also be formed as a common layer of conductive material. The connection between the two rear capacitor plates may also be formed in this layer. In some embodiments this can allow the whole assembly to be made using just two steps of patterning a surface conductive layer on a substrate, one layer being provided on the front surface of the substrate and the other layer on the rear surface.

The present invention further provides a method of producing a resonant RF detector comprising:
providing a test substrate;
forming a test coil on a front surface of the test substrate;
forming two test capacitors each having two plates on opposite surfaces of the test substrate;
providing electrical connection between the capacitors and the coil and each other;
adjusting the size of at least one of the capacitor plates until the test coil and test capacitors meet a performance criterion;
determining the size of the test capacitors after the adjusting;
and subsequently producing the coil assembly so that it has a substrate and coil corresponding in size and shape to the test substrate and coil and two capacitors of the determined sizes.

In one embodiment the target application is a catheter-based probe for magnetic resonance imaging of the bile duct, but similar approaches would be appropriate for vascular imaging, or for other forms of internal magnetic resonance imaging such as oral, rectal or vaginal imaging that require a small flexible probe.

The overall aim of some embodiments of the invention is a resonant detector in the form of a flexible sheet that may be wrapped around a catheter and connected to receive electronics, for example via a subminiature co-ax cable.

In some embodiments a three-stage approach is used. In the first, a RF resonator is formed from a micro-fabricated coil and discrete capacitors. Conventional matching and tuning of this structure allows the values of C_{M} and C_{T} to be found. In the second, a fully integrated device is constructed. The same design of coil is used, together with micro-fabricated capacitors whose areas are estimated from the previous experimental values of C_{M} and C_{T}. Mechanical trimming of the capacitors following a systematic procedure then allows exact matching and tuning. In the third, a fully integrated device is constructed using an identical micro-fabrication process, but with the now-known capacitor areas. The result is a flexible monolith requiring only connection to a co-axial output, and the method is easily applicable to other coil arrangements.

Preferred embodiments of the present invention will now be described by way of example only with reference to the accompanying drawings.

### BRIEF DESCRIPTION OF THE DRAWINGS

FIG. 1a is a circuit diagram of a detector coil;

FIG. 1b is a diagram of an equivalent circuit to that of FIG. 1a;

FIG. 1c is a diagram of a further equivalent circuit to that of FIG. 1b;

FIG. 2 is a graph of normalized impedance as a function of normalized coil resistance in the circuit of FIG. 1a;

FIG. 3 is a graph showing the dependence of capacitance on coil resistance at different field strengths in the circuit of FIG. 1a;

FIG. 4a is a diagram of a known detector coil assembly;

FIG. 4b is a diagram of a detector coil assembly according to an embodiment of the invention;

FIG. 5 is a side view of and expanded section through the coil assembly of FIG. 2 mounted on a catheter;

FIG. 6a is a front view of a set of detector coil assemblies according to the invention;

FIG. 6b shows one of the detector coil assemblies of FIG. 6a before and after trimming;

FIG. 6c is an enlarged view of the part of the detector coil assembly of FIG. 6b;

FIG. 7 is a graph showing variation of S₁₁ for RF detectors with different coil lengths held flat and mounted on a catheter;

FIG. 8 is a graph showing variation of S₁₁ with frequency for a detector coil assembly according to the invention mounted on a catheter at different stages of matching and tuning, and variation of S₂₁ at the final stage;

FIG. 9 is a graph showing variation of S₁₁ with frequency for a detector assembly according to the invention mounted on a catheter;

FIG. 10 is a photograph of a catheter with a detector coil assembly according to an embodiment of the invention mounted on it;

FIG. 11 is a photograph of a test phantom;

FIG. 12 is a Sagittal ¹H MR image of the test phantom of FIG. 11 obtained at 1.5 T, using a fully integrated RF detector with a 40 mm long coil;

FIG. 13 is a diagram of a detector coil assembly according to a further embodiment of the invention;

FIG. 14 is a circuit diagram of the equivalent circuit of the assembly of FIG. 13; and

FIG. 15 illustrates the opposite winding sense of the sections of the coil assembly of FIG. 13.

### DESCRIPTION OF THE PREFERRED EMBODIMENTS

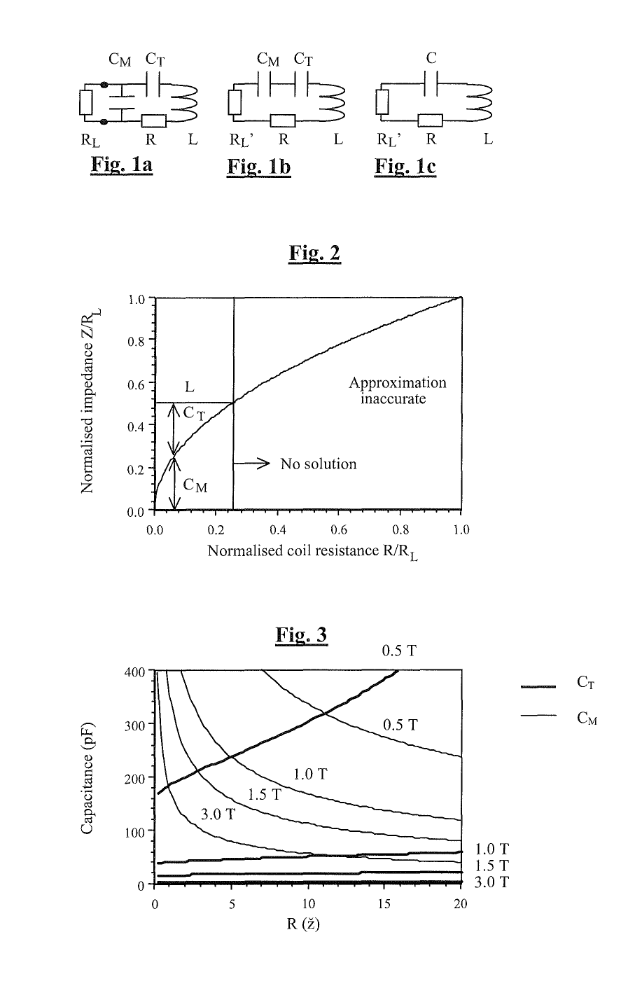

Referring to FIG. 1a, according to the standard theory of matching, a lossy inductor with inductance L and resistance R whose impedance at angular frequency ω is R+jωL can be tuned to angular resonant frequency ω₀ and matched to a load R_{L} using two capacitors C_{M} and C_{T}.

The admittance of the combination of R_{L} and C_{M} is Y=1/R_{L}+jωC_{M}. Hence, the corresponding impedance Z=1/Y can be found as:

Z=(1/jωC_{M}){1/(1+1/jωC_{M}R_{L})} (1)

If ωC_{M}R_{L}>>1, Equation 1 may be approximated as:

Z≈1/jωC_{M}+1/(ω²C_{M}²R_{L}) (2)

This approximation assumes that R_{L}>>1/ωC_{M}, i.e. that the load is much greater than the modulus of the impedance of C_{M}. Equation 2 implies that Z is equivalent to a capacitor C_{M} in series with a frequency-dependent load R_{L}′=1/(ω²C_{M}²R_{L}) as shown in FIG. 1b. The matching capacitor C_{M} therefore effectively inserts a scaled version of the load R_{L}′ into the resonant circuit. If C_{M} is too small, R_{L}′ will be too large, and the overall quality factor of the resonator will be reduced. If C_{M} is too large, R_{L}′ will be too small and little signal will be detected. Matching involves choosing C_{M} so that R_{L}′=R at resonance, which requires:

C_{M}=1/{ω₀√(RR_{L})} (3)

This result implies that 1/ω₀C_{M}=√(RR_{L}), i.e. that the modulus of the impedance of C_{M} should equal the geometric mean of the two resistors that require matching. C_{M} must clearly reduce as the frequency rises or as resistive losses increase. We may then rewrite the condition for the earlier approximation as R_{L}>>R. Since R_{L} will typically be 50Ω, and R a few Ohms, Equation 3 will be almost universally valid, independent of the value of L and the operating frequency.

The circuit of FIG. 1b is then equivalent to the simple resonator in FIG. 1c. Here, C_{M} and C_{T} have been combined into a single equivalent capacitor C, whose value C=1/(ω₀²L) is the total capacitance needed to achieve resonance. Once C_{M} has been fixed, the tuning capacitor C_{T} should then be chosen so that 1/C_{T}+1/C_{M}=1/C, or:

C_{T}=CC_{M}/(C_{M}−C) (4)

Clearly, C_{T} must be positive and finite to achieve a meaningful solution. This condition requires C_{M}>C, or ω₀L>√(RR_{L}), so that modulus of the impedance of the inductor must exceed the geometric mean of the two resistors. This condition can normally be satisfied, provided the coil resistance R is low enough. The impedance matching problem may be illustrated graphically as shown in FIG. 2. Here we plot the variation of the normalised impedance moduli Z/R_{L} for C_{M} and C_{T}, and for an arbitrary assumed inductance L, as a function of the normalised coil resistance R/R_{L}. Provided R/R_{L} is small enough and ω₀L is large enough, there will be a solution and the relevant approximations will be valid.

The operating frequency f₀ for ¹H magnetic resonance (MR) scales linearly with flux at 42.57 MHz/T. In a 1.5 T system (for example), f₀=63.5 MHz. FIG. 3 shows example dependencies of C_{M} and C_{T} on the coil resistance R obtained from Equations 3 and 4 at different field strengths, assuming an inductance of 0.35 pH for comparison with later experimental results and a 50Ω load. At low field strengths, high capacitances are required to reach the relatively low resonant frequency required, and both C_{T} and C_{M} vary significantly. As the field strength and resonant frequency rise, C_{T} reduces considerably and becomes more and more constant. C_{M} also reduces, but its value still varies significantly, rising rapidly as the coil resistance reduces. In this range, C_{M} can considerably exceed C_{T}.

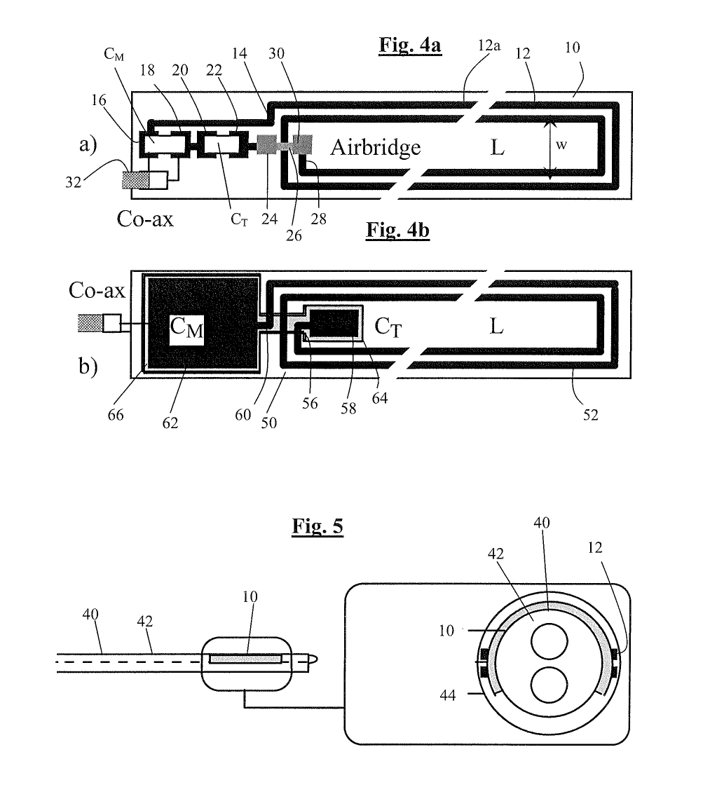

In a first stage of a method of producing detector coils according to an embodiment of the invention, hybrid integrated RF detectors are first produced. Referring to FIG. 4a a hybrid integrated detector consists of a substrate layer 10 with a two-turn rectangular spiral winding or coil 12 formed on its surface. The outer end 14 of the winding 12 is connected to the first of four connector pads 16, 18, 20, 22 for surface mount capacitors C_{M} and C_{T}. The second and third connector pads 18, 20 are connected together and the fourth connector pad 22 is connected to a further contact 24, on the outside of the winding 12 for connection to one end of an air bridge 26. The inner end 28 of the winding 12 is connected to a further contact 30 for the other end of the air bridge 26, and the air bridge 26 extends over the winding 12 connecting the two air bridge contact pads 24, 30. Two capacitors, a matching capacitor C_{M} and a tuning capacitor C_{T}, can be connected in series between the first and second 16, 18 and the third and fourth 20, 22 connector pads to form a closed circuit in series with the winding 12 and air bridge 26. Two outputs, for example the inner and outer of a coaxial cable 32, are connected to the first and second connector pads 16, 18 so that the outputs are connected across the matching capacitor C_{M}.

Referring to FIG. 5 the coils of this embodiment were designed for attachment to a catheter 40. The catheter 40 has a tubular body 42 of circular cross section with two lumens 43 extending through it. The coil assembly is arranged so that the long sides 12a of the rectangular coil 12 are parallel to the longitudinal axis of the catheter 40, and the flexible substrate 10 is wrapped round the catheter 40, and a shrink-wrap sleeve 44 placed over the coil assembly to hold it in place on the catheter 40. The width of the coil 12, in this case measured from a point between the inner and outer turns on one side of the coil to a point between the inner and outer turns on the opposite side of the coil, is arranged to be equal to half the circumference of the catheter 40. The two sides 12a of the coil 12 therefore extend along opposite sides of the catheter 40.

The devices of FIG. 4a are fabricated using three lithographic steps. The first defines the majority of the conductors, including the coil 12, the connector pads 16, 18, 20, 22, and the contact pads 24, 30, which are formed simultaneously on the surface of the substrate 10 as a single layer by electroplating inside a photoresist mould. The second step defines a set of holes in an insulating plastic layer formed over the electroplate layer, which allow access to the landing pads and some conductor ends. The third step defines the air bridge 26 that allows connection of the components outside the winding 12 to the inner side of the spiral winding. Coils with this geometry were designed for ¹H MRI at 1.5 T, with the following parameters: conductor width 200 μm, conductor separation 100 μm, coil length 60 mm, and coil width 4.2 mm. The last value was chosen to place the long conductors on the diameter of an 8 Fr (2.7 mm dia) catheter, when the detector was wrapped around the catheter with its long axis parallel to the catheter.

Coils were fabricated on 25 μm thick polyimide film (Kapton® HN, DuPont, Circleville, Ohio). This material is mechanically and thermally stable, flexible, pinhole free, resistant to dielectric breakdown, and commercially available in a range of thicknesses [Data Sheet HK-15345: DuPont Kapton® HN polyimide film” DuPont High Performance Films, Circleville, Ohio, http://www.dupont.com]. To provide a rigid surface for processing, the film was first stretched over a 100 mm diameter silicon wafer and anchored using Kapton® tape. Seed layers of Ti (30 nm) and Cu (200 nm) metal were then deposited by RF sputtering. A layer of AZ 9260 thick positive photoresist (Microchemicals GmbH, Ulm, Germany) was then deposited by spin coating, and patterned using UV contact lithography to form a mould. 20 μm thick Cu conductor tracks were then formed by electroplating inside this mould, using Technic FB Bright Acid copper plating solution (Lektrachem Ltd., Nuneaton, UK). The mould was stripped, and exposed seed layer was removed by etching. A 2.5 μm thick layer of SU-8 2000 negative epoxy photoresist (Microchem Corp., Newton, Mass.) was then deposited and patterned to act as an interlayer. Finally, the air bridge was formed, by repeating the steps of seed layer deposition, mould formation, plating, mould removal and seed layer etching. The Kapton® sheet was detached from its carrier, and individual devices were separated using a scalpel. The devices were highly flexible, and could be distorted considerably without conductor detachment.

Electrical performance was measured using an Agilent E5061A network analyser. Matching to R_{L}=50Ω and tuning were carried out with the coil loosely attached with heat shrink tubing to an 8 Fr dual lumen catheter, using discrete 0805 series non-magnetic capacitors (SRT Micro Céramique, France). The additional components were located just beyond the end of the catheter, and a length of 0.8 mm diameter non-magnetic 50Ω Bluetooth co-axial cable (Axon Cable, Dunfermline, UK) was connected across C_{M} and passed down one of the catheter lumens. The heat shrink was then tightened to protect the coil, capacitors and cable joint. Matching and tuning were achieved by minimising the value of the scattering parameter S₁₁ at 63.8 MHz using component values of C_{M}=139 pF, C_{T}=19.5 pF. Ignoring self-capacitance, these values imply a total capacitance of C=17.1 pF, a coil inductance of L=1/(ω₀²C)=0.36 μH and a resistance of R=1/(ω₀²C_{M}²R_{L})=6.4Ω (and hence a quality factor of Q=ω₀L/R=23). Confirmation of the Q-factor was provided by measurement of the frequency variation of sensitivity for completed resonators.

Referring to FIG. 4b, fully integrated resonators were then constructed, using integrated parallel plate capacitors. These assemblies comprised a substrate 50 of the same material and of the same thickness as that 10 of FIG. 4a, and a winding or coil 52 on its front side of the same dimensions and materials as that 12 of FIG. 4a. The coil 52 is broken between its inner and outer ends. The inner end 56 of the winding is connected to a rectangular capacitor plate 58 located within the coil winding 52 and forming part of a tuning capacitor C_{T}, and the outer end 60 of the winding is connected to a rectangular capacitor plate 62 located outside the coil and forming part of a matching capacitor C_{M}. Each of the capacitors C_{T}, C_{M} also comprises a second, rear plate formed on the rear of the substrate 50, the two rear plates 64, 66 being connected to each other. The substrate 50 itself therefore is used as the interlayer between the plates of each capacitor, and as it is formed of thin (12.7 μm) Kapton this allows the plate sizes to be kept small. The two plates 62, 66 of the matching capacitor C_{M} are connected to an output.

The coil assembly of FIG. 4b is produced using a front side pattern which consists of a spiral, forming the coil 52, linked to the two front capacitor pads 58, 62, while the rear side pattern consists of the pair of similar rear pads 64, 66 linked directly together by a connecting area of conducting material. This arrangement places a larger capacitor C_{M} outside the coil winding, allowing connection of the two plates 62, 66 of that capacitor to an output, which can again be a co-axial output, and a smaller capacitor C_{T} inside the coil. Because no air bridge is needed to provide connection to the inner end of the spiral, the entire layout may be fabricated using just two lithographic steps to define conductors on either side of the substrate. Double-sided lithography and electroplating are required, but front-to-back alignment is not critical since the capacitor plates need only overlap, at least partially, and do not need to be exactly aligned with each other.

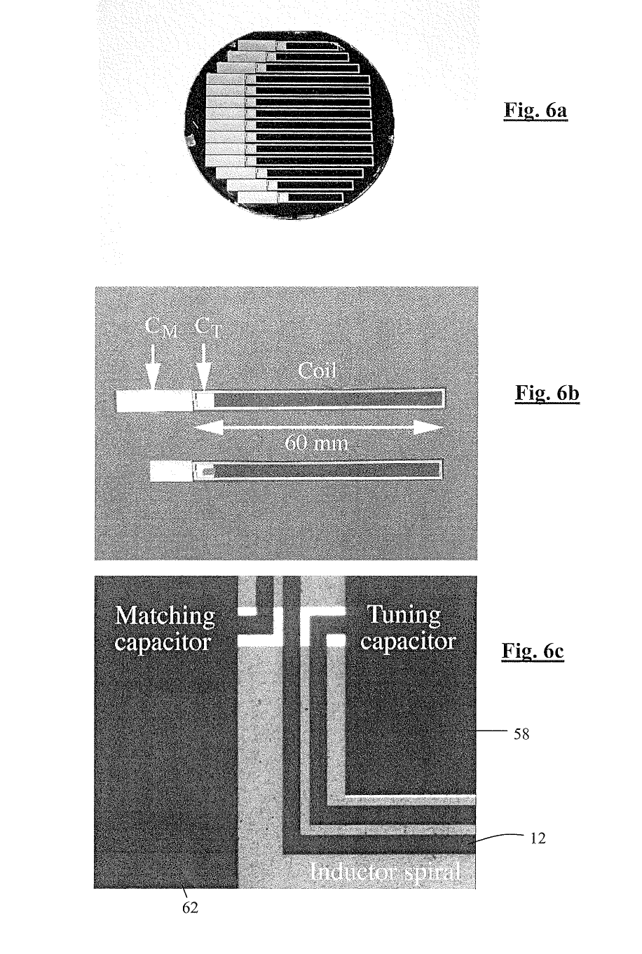

Prototype devices were fabricated using conductor dimensions similar to those above, but a number of coil assemblies in a range of coil lengths were formed on a single substrate as shown in FIG. 6a. To allow adjustment of capacitance only by removal of material, capacitors were fabricated using estimated values approximately double those found experimentally. Dimensions of 18 mm×5.5 mm (99 mm²) and 4 mm×3.5 mm (14 mm²) were used for C_{M} and C_{T}; assuming a relative dielectric constant of 3.5 for Kapton® [“Data Sheet HK-15345: DuPont Kapton® HN polyimide film” DuPont High Performance Films, Circleville, Ohio, http://www.dupont.com], this yielded initial capacitances of 240 pF and 34 pF respectively. Using processes designed for 100 mm silicon wafers, 14 devices of different length could be fabricated per substrate, as shown in FIG. 6a.

Similar patterning and electroplating processes were used to form the conductors on each side. The rear side conductors were formed first, using a smaller Cu thickness (5 μm) and then protected with a layer of photoresist while the front side conductors were formed with the standard Cu thickness (20 μm). The overall thickness was therefore approximately 40 μm. FIG. 6a shows a completed substrate as described above, FIG. 6b shows a pair of completed elements, and before and one after trimming, and FIG. 6c an enlarged view in the region of the capacitors, showing part of the coil 12 and the capacitor plates 58, 62 on the front surface of the substrate 10. The resulting devices resonated immediately when placed near an inductive probe.

Matching and tuning of fully integrated devices was then carried out by mechanically trimming each of the matching and tuning capacitors C_{M} and C_{T}, using a systematic process.

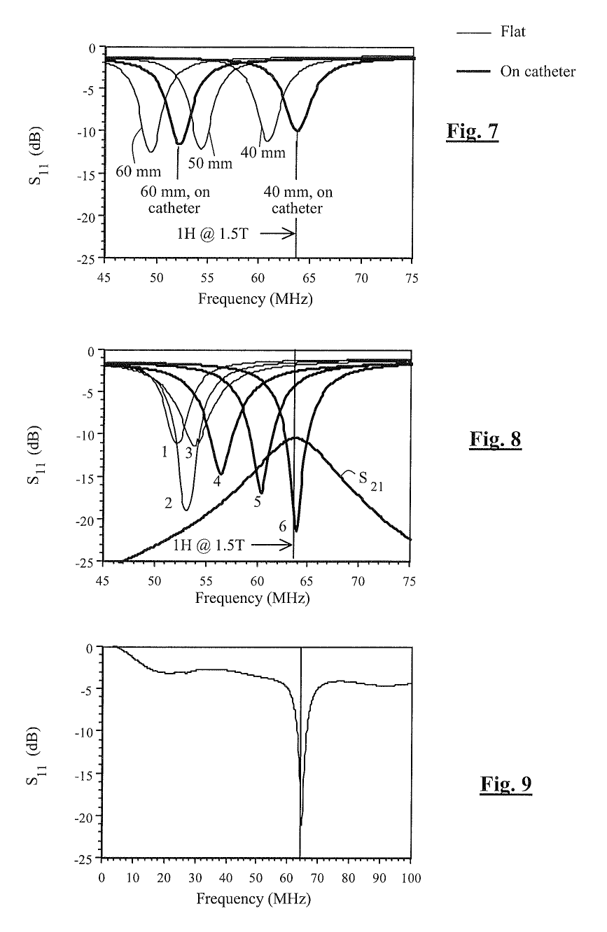

Completed devices were connected electrically using subminiature co-ax cable, which was soldered across C_{M}. The initial condition of each device was then assessed, by measuring the frequency variation of the scattering parameter S₁₁ with the devices held flat. FIG. 7 shows measurements obtained from devices with different coil lengths. In each case, a minimum in S₁₁ near a particular frequency implies the existence of a resonance, and the sharpness and depth of the minimum suggests good Q-factor and reasonable impedance matching. The resonant frequency decreases with coil length, and in each case lies below 63.8 MHz. However, the impedance matching reduces as the resonant frequency rises.

The devices were then mounted on a short section of 8 Fr catheter, and the frequency variation of S₁₁ was re-measured. This process would be expected to reduce L without changing R, and hence simply increase the resonant frequency. In each case, the matching degraded. Since the effective load is R_{L}=1/(ω₀²C_{M}²R_{L}), and C_{M} and R_{L} are both fixed, the only possible conclusion is that C_{M} is too large, in line with earlier estimates. The shortest (40 mm) device re-tuned immediately to 63.8 MHz frequency. However, since the longest (60 mm) device only re-tuned to 52 MHz, this device required adjustment.

Matching and tuning of the 60 mm device was carried out as shown in FIG. 8, which shows frequency variations of S₁₁ at different stages. Starting from the initial condition (state 1), C_{M} was first trimmed with a scalpel. After several adjustments, state 2 was reached. Here, the depth of the minimum in S₁₁ suggests excellent matching, but at the wrong resonant frequency (which has only risen slightly, to 53 MHz). However, because impedance matching occurs at a particular value of ω₀C_{M}, the capacitance C_{M} needed to match at a one angular frequency (ω₀) can be used to estimate the value C_{M}′ needed at another (ω₀′), as C_{M}′/C_{M}=ω₀/ω₀′. It was therefore simple to estimate the optimum area of matching capacitor required at 63.8 MHz, and C_{M} was trimmed appropriately to state 3. Here the resonant frequency has again risen slightly (to 54 MHz) and the impedance matching appears to have degraded. The tuning capacitor C_{T} was now trimmed through states 4 and 5, gradually increasing the resonant frequency and improving the matching, to the final state 6. At this point, the accuracy of the tuning and matching are both excellent. The Q-factor of tuned and matched device was again estimated as 22, by measuring the frequency variation of S₂₁ using an inductive probe as shown in FIG. 8.

The final areas of C_{M} and C_{T} were 52 mm² and 9.3 mm², respectively, corresponding to estimated capacitances of 127 pF and 23 pF (close to the target values). These results show that a method for identifying the initial state of an unknown device exists, and (provided the two capacitances are both too large), there is a convergent algorithm to match and tune by reduction of overlap areas. However, if necessary adjustment can still be carried out when capacitors are too small, simply by extending overlap areas with silver-loaded epoxy.

It can be a problem that mechanical trimming can short one of the capacitors, due to small slivers of metal tracking between the closely spaced conductors. This problem can be eliminated, by replacing mechanical trimming of the entire structure with laser trimming of just one, or both, of the conductors, so that an insulating dielectric layer remains in place throughout. In addition, excess solder flow during cable attachment can spoil the flexibility of the metal layers. This problem can be addressed using additional patterned surface layers to limit the solderable area.

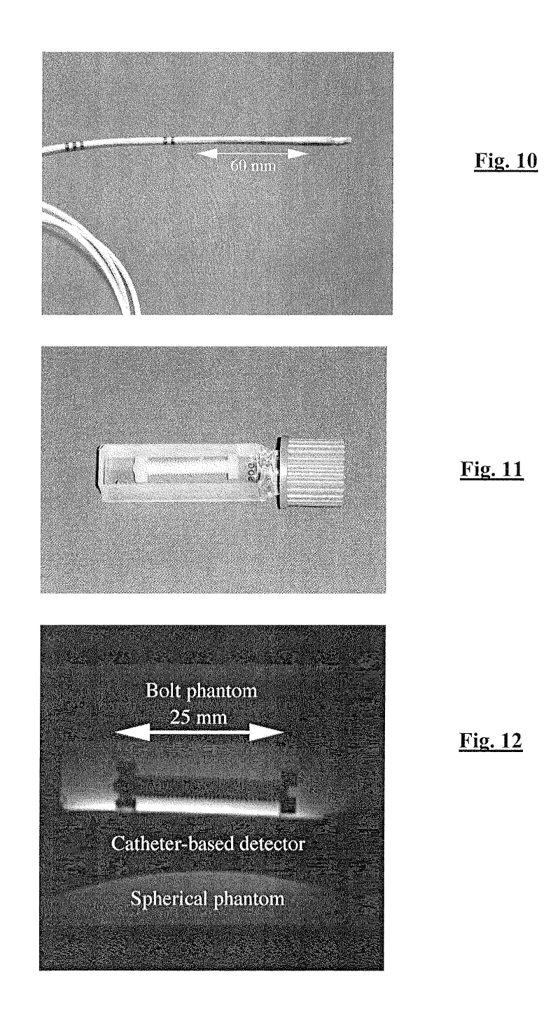

Once the final area is known, a mask redesign may be carried out to fabricate further devices whose initial state is even closer to the desired final state. FIG. 9 shows the frequency variation of S₁₁ of a device fabricated with the capacitor areas determined from the capacitor trimming and testing described above. This device is inherently tuned and matched, and requires only a soldered connection to an output to operate. FIG. 10 is a photograph of a completed catheter-based RF micro-coil detector.

¹H magnetic resonance imaging experiments were carried out on phantoms, using resonators as described above with reference to Figures 6a to c to demonstrate the imaging capability of these integrated resonators.

Imaging was performed using a 1.5 T GE HD Signa Excite scanner. The system body coil was used for transmission and a 40 mm long catheter mounted micro-coil as shown in FIG. 5 was connected to the auxiliary coil input for signal reception. No measures (such as diode-switched detuning) were taken to avoid damage by the transmit pulse, since previous experience suggested this to be unnecessary. The micro-coil was initially placed on a large spherical phantom containing a dilute solution of NiCl₂ and CuSO₄. The micro-coil was located at the isocentre with the long conductors lying in the coronal plane, and autotuned using a fast recovery fast spin echo (FRFSE) sequence.

High-resolution imaging was then demonstrated using a phantom consisting of an M4 nylon nut and cheese-head bolt (tooth pitch 0.7 mm), which was placed in solution in a small glass cuvette as shown in FIG. 11. The cuvette was placed on top of the coil, which remained on top of the spherical phantom. Imaging was carried out using a relaxation recovery time (TR) of 33 ms, an echo time (TE) of 15 ms and a flip angle of 10°. The images were acquired using a T₂-weighted FRFSE sequence in 28 slices of 1.2 mm thickness, with 256×224 pixels per slice in an 80 mm×40 mm field of view. With 6 excitations to improve SNR the total acquisition time was 11 min 53 sec.

FIG. 12 is a typical sagittal slice, which shows the cuvette containing the nut and bolt at the top of the figure and the spherical phantom at the bottom. The slotted head of bolt is clearly visible, and in the original images the teeth may also be seen. These results are comparable to those previously obtained in with partially integrated coil assemblies as shown in FIG. 4a [Ahmad M. M., Syms R. R. A., Young I. R., Mathew B., Casperz W., Taylor-Robinson S. D., Wadsworth C. A., Gedroyc W. M. W. “Catheter-based flexible microcoil RF detectors for internal magnetic resonance imaging” J. Micromech. Microeng., submitted], and demonstrate that the imaging performance of fully integrated coils can be as good as that of coils with surface mount capacitors.

In addition to providing a means of realising spiral coils with integrated tuning and matching capacitors, as described in the embodiments above, other embodiments of the invention make use of its ability to allow more complex coil arrangements, which can have advantages in certain applications.

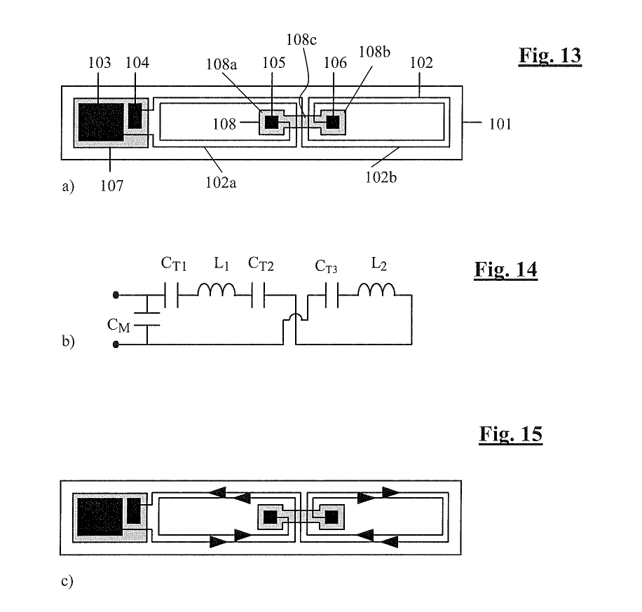

Referring to FIG. 13 in a further embodiment, a two-turn, figure-of-eight coil with tuning and matching capacitors is provided. The circuit is again constructed from a thin substrate layer 101 with the coil windings 102 formed on its front surface, from a first track 102a and a second track 102b. The first track 102a extends from the matching capacitor front plate 103 and spirals inwards through one and a half turns, to form the first loop 102a of the winding, and ends with a first interconnection capacitor plate 105 inside the first loop. It therefore forms all of the first loop except one half turn. The second track 102b extends from the tuning capacitor front plate 104 along the substrate adjacent to the first track to form a half turn of the first loop 102a, and then spirals inwards through two complete turns to form the whole of the second loop 102b of the figure-of-eight, ending with a second interconnection capacitor plate 106 inside the second loop. An interconnection bridge 108 is formed on the back surface of the substrate 101 and comprises two plates 108a, 108b each of which is opposite one of the interconnection capacitor plates 105, 106, coupled together by a short track 108c. A further plate 107 on the back surface of the substrate 101 forms the back plates of the matching and tuning capacitors. Both the tuning capacitor and the matching capacitor have their front plate 103, 104 outside the coil 102.

The resulting winding on the front face of the substrate has two loops each having two full turns, the winding being broken in the outer turn at one end of the first loop, to allow connection to two plates 103 and 104 and also broken at its centre where the resulting gap, between the two capacitor plates 105 and 106 which form ends of the coil on the front face, is bridged by the interconnecting bridge 108.

The arrangement of FIG. 13 has the equivalent circuit shown in FIG. 14. The coil 102 provides an inductance L, divided into two sections L₁ and L₂. The plates 103 and 107 together with the substrate 101 provide a matching capacitor C_{M}, while the plates 104 and 107 together with the substrate 101 provide a first tuning capacitor C_{T1}. The plates 105 and 108a together with the substrate 101 provide a second tuning capacitor C_{T2}, while the plates 106 and 108b together with the substrate provide a third capacitor C_{T3}. The angular resonant frequency of the circuit is then:

ω₀=1/(LC)^{1/2} (5)

Where L is the total inductance and C is the total capacitance, and L and C are given by:

L=L₁+L₂ (6)

1/C=1/C_{M}+1/C_{T1}+1/C_{T2}+1/C_{T3} (7)

It will be appreciated that the circuit can operate as a resonant detector for RF signals, and that matching and tuning may be carried out as described above for the embodiment of FIG. 4b. It will also be appreciated that the function of the capacitors C_{T2} and C_{T3} is to allow a figure-of-eight coil arrangement to be realised from two patterned conducting layers formed on either side of an insulating substrate, without the need for an air bridge or a via connection. It will also be appreciated that the winding of the coil is divided into two halves, with an opposite winding sense in each half, as shown in FIG. 1c. Each half, or loop, has the same number of turns.

It will be appreciated that if the inductors L₁ and L₂ are identical, a uniform time-varying external magnetic flux B₁ acting perpendicular to the coil will induce equal and opposite emf in each half winding, which will therefore cancel to yield zero net emf and zero current. Consequently, the coil will have low sensitivity to a spatially uniform RF magnetic field, such as the field generated by the body coil of a MRI scanner during excitation. As a result, directly induced voltages and local modification of the excitation pattern may be minimised. However, the coil can still have sensitivity to the locally generated RF fields that arise during signal reception.

This feature provides an inherent passive de-coupling between the transmitter and receiver of the MRI system, which can avoid the need for other methods of de-coupling such as diode-switched de-tuning. Consequently, the arrangement can provide a de-coupled coil in thin-film form, that can be fabricated entirely by patterning of conductor layers without the need for additional semiconductor components.

Finally, it will also be appreciated that the use of paired capacitors to allow a figure-of-eight coil winding without the use of an airbridge can be extended to provide windings that are further subdivided into additional sections, providing a multi-section coil whose winding alternates in sense between adjacent sections or loops. If there are an even number of sections, then the induced emfs in the sections can be balanced by making all of the loops the same size and with the same number of turns. In other cases the sections can be of different sizes, and there may be different numbers of sections with the two winding senses, but with the correct selection of coil size and shape, the emfs can still be balanced.

1. A resonant radiofrequency (RF) detector assembly comprising a substrate having a front surface and a rear surface, a coil having two ends and being formed on the front surface of the substrate, and two capacitors, each capacitor having a front plate which is formed on the front surface of the substrate and a rear plate formed on the rear surface of the substrate, the two front plates each being electrically connected to a different end of the coil, and the two rear plates being electrically connected to each other.

2. An assembly according to claim 1 wherein the front plate of one of the capacitors is formed within the coil.

3. An assembly according to claim 1 wherein the front plate of one of the capacitors is formed outside the coil.

4. An assembly according to claim 1 comprising a layer of conductive material forming the two front capacitor plates and the inductor.

5. An assembly according to claim 1 comprising a layer of conductive material forming the two rear capacitor plates.

6. An assembly according to claim 1 wherein the substrate, coil and capacitors are flexible.

7. An assembly according to claim 1 wherein the coil has two sections and each of the front plates is connected to a respective one of the sections.

8. An assembly according to claim 7 wherein the sections each have a respective winding sense, the winding senses being opposite to each other.

9. An assembly according to claim 8 wherein the sections each have the same number of turns.

10. An assembly according to claim 7 wherein each of the coil sections forms a respective loop and each of the front plates is inside a respective one of the loops.

11. A method of producing a resonant RF detector comprising: providing a substrate having a front surface and a rear surface; forming a coil on the front surface of the substrate; forming two front capacitor plates on the front surface of the substrate; forming two rear capacitor plates on the rear surface of the substrate each at least partially aligned with one of the front capacitor plates to form a capacitor, and providing electrical connection between the front capacitor plates and the coil and between the two rear capacitor plates.

12. A method according to claim 11 wherein the coil and the front capacitor plates are formed simultaneously on the front surface of the substrate as a common layer of conductive material.

13. A method according to claim 7 wherein the rear capacitor plates are formed simultaneously on the rear surface of the substrate as a common layer of conductive material.

14. A method of producing a resonant RF detector comprising: providing a test substrate having a front surface and a rear surface; forming a test coil on the front surface of the test substrate; forming two test capacitors each having two plates on opposite surfaces of the test substrate; and providing electrical connection between the capacitors and the coil and between the two capacitors; defining a performance criterion, adjusting the size of at least one of the capacitor plates until the test coil and test capacitors meet the performance criterion; determining the size of the test capacitors after the adjusting; and subsequently producing the coil assembly so that it has a substrate and coil corresponding in size and shape to the test substrate and coil and two capacitors of the determined sizes.

15. A method according to claim 14 wherein the size of at least one plate of each of the capacitors is adjusted.

16. A method according to claim 14 wherein the performance criterion comprises at least one of: a degree of matching the impedance seen across one capacitor at a predetermined frequency to a predetermined electrical load, and a degree of tuning the resonant frequency of the circuit to a predetermined value.
